(19) United States
(12) Patent Application Publication
(10) Pub. No.: US 2017/0043554 A1
(43) Pub. Date: Feb. 16, 2017

(54) TRANSPARENT CONDUCTIVE FILM

(71) Applicant: NITTO DENKO CORPORATION, Ibaraki-shi, Osaka (JP)

(72) Inventors: Nozomi Fujino, Ibaraki-shi (JP); Daiki Kato, Ibaraki-shi (JP); Tomotake Nashiki, Ibaraki-shi (JP)

(73) Assignee: NITTO DENKO CORPORATION, Ibaraki-shi, Osaka (JP)

(21) Appl. No.: 15/304,785

(22) PCT Filed: Apr. 9, 2015
(86) PCT No.: PCT/JP2015/061124

§ 371 Date: Oct. 17, 2016

(30) Foreign Application Priority Data
Apr. 17, 2014 (JP) 2014-085584
Apr. 6, 2015 (JP) 2015-077614

(51) Int. Cl. B32B 7/02; G06F 3/041; H01B 1/08; H01B 5/14; C23C 14/10; C23C 14/34

(52) U.S. Cl. CPC B32B 7/02; C23C 14/10; C23C 14/34; H01B 1/08; H01B 5/14; G06F 3/0416; B32B 2307/202; B32B 2307/412; B32B 2307/538

(57) ABSTRACT

Provided is a transparent conductive film having excellent moist-heat resistance and capable of maintaining a low specific resistance value. The present invention relates to a transparent conductive film including: a transparent film substrate; at least three undercoat layers; and a crystalline transparent conductive layer in this order, wherein: the at least three undercoat layers include: a first undercoat layer formed by a wet coating method; a second undercoat layer that is a metal oxide layer having an oxygen deficient; and a third undercoat layer that is a metal oxide layer having a stoichiometric composition from a side of the film substrate; the transparent conductive layer has a surface roughness Ra of 0.1 nm or more and 1.6 nm or less; and the transparent conductive film has specific resistance of 1.1×10⁻⁴ Ω·cm or more and 3.8×10⁻⁴ Ω·cm or less.

### TECHNICAL FIELD

The present invention relates to a transparent conductive film.

### BACKGROUND ART

In a touch panel display device which has recently been spread at a high rate, a transparent electrode including a transparent conductive layer made of an indium-tin composite oxide (ITO) or the like has been used. Although a conductive body with a transparent electrode used for a touch panel fundamentally uses a glass or plastic film as a substrate, a transparent conductive film using a plastic film is preferably used in a smart phone or tablet particularly requiring portability from the viewpoint of thinness and weight.

In recent years, improvements in the sensor sensitivity or resolution of the transparent electrode have been demanded against the background of the high grade of the touch panel. As a result, the level of the specific resistance value required for the transparent conductive layer tends to be increasingly decreased.

In the meantime, since the transparent conductive layer is brittle, the transparent conductive layer is easily deteriorated under the influence of external factors, which is apt to cause an increase in a specific resistance value. Therefore, in order to keep the specific resistance value of the transparent conductive film low, it is necessary to improve the maintenance reliability of the specific resistance value of the transparent conductive film so as to numerically decrease the specific resistance value of the transparent conductive layer and to allow the value to be maintained as much as possible.

One of the external factors causing the deterioration is heat or water. Generally, the transparent conductive layer has problematic moist-heat durability, which is apt to easily cause an increase in the specific resistance value in a moist-heat environment. For this reason, in the use of a touch panel mounted on a smart phone and a car navigation system or the like which may be placed in a high temperature-high humidity environment, high moist-heat durability causing no problem for operation is strongly demanded even under a severe condition represented by 85° C. and 85% RH, for example.

As means for improving the moist-heat durability, a multilayer film (see Patent Document 1) and a transparent conductive film (see Patent Document 2) have been proposed. In the multilayer film, a first thin film layer, a second thin film layer, and a transparent conductive film are provided on one surface of a transparent resin substrate. The multilayer film has water vapor transmission rate of 1.0 g/m²·day or less in 40° C. and 90% Rh. In the transparent conductive film, a transparent conductive thin film made of an indium-tin composite oxide is provided on one surface of a transparent film substrate with an SiOₓ (x=1.0 to 2.0) thin film sandwiched therebetween. The SiOₓ thin film has a thickness of 10 to 100 nm, a light refractive index of 1.40 to 1.80, and an average surface roughness Ra of 0.8 to 3.0 nm.

### PRIOR ART DOCUMENTS

### Patent Documents

Patent Document 1: JP-B1-5245893

Patent Document 2: JP-B1-3819927

### SUMMARY OF THE INVENTION

### Problems to be Solved by the Invention

However, the transparent conductive layer described in the documents has a comparatively high specific resistance value, which cannot achieve moist-heat resistance which can endure practical use at the level of a specific resistance value of 3.8×10⁻⁴ Ω·cm or less.

Specifically, in Patent Document 1, the surface roughness of the transparent conductive layer is not considered for the securement of moist-heat resistance. The specific resistance value of the transparent conductive layer is also comparatively high. In Patent Document 2, only the formation of an undercoat layer by a dry type coating method is disclosed as the method for controlling a surface roughness. The number of the undercoat layers is one, which has room for improvement for achieving both interlayer adhesion and a film density.

A coefficient of fluctuation from the reference value of a specific resistance value caused by the deterioration in a transparent conductive layer in the range of a low specific resistance value is relatively increased as compared with that in the range of a high specific resistance value. Therefore, the conductive film having low specific resistance is apt to bring about obstacles caused by deterioration in the real use, and requires higher moist-heat resistance. On the other hand, in recent years, from the viewpoint of securing a high display quality in the touch panel, a transparent conductive layer tends to be thinner and brittler in order to improve light transmittance. Thus, while the moist-heat resistance is being thought as important in the present field, the securement of the moist-heat resistance becomes more difficult.

The present invention has been made in view of the problems, and it is an object of the present invention to provide a transparent conductive film having excellent moist-heat resistance and capable of maintaining a low specific resistance value.

### Means for Solving the Problems

As a result of wholehearted research of the present inventors to solve the conventional problems, it was found that the object can be achieved by adopting the following constitution, leading to the completion of the present invention.

That is, the present invention relates to a transparent conductive film including: a transparent film substrate; at least three undercoat layers; and a crystalline transparent conductive layer in this order,

wherein: the at least three undercoat layers include: a first undercoat layer formed by a wet coating method; a second undercoat layer that is a metal oxide layer having an oxygen deficient; and a third undercoat layer that is a metal oxide layer having a stoicheiometric composition from a side of the film substrate;

the transparent conductive layer has a surface roughness Ra of 0.1 nm or more and 1.6 nm or less; and

the transparent conductive film has specific resistance of 1.1×10⁻⁴ Ω·cm or more and 3.8×10⁻⁴ Ω·cm or less.

The transparent conductive layer is crystalline, which allows an improvement in transparency, and provides high moist-heat durability even if the transparent conductive layer is a thin film.

In order to reduce the specific resistance of the transparent conductive layer, it is necessary to decrease the surface roughness Ra of the transparent conductive layer. In the transparent conductive film, the surface roughness Ra of the crystalline transparent conductive layer is decreased to the range of 0.1 nm or more and 1.6 nm or less, which can reduce the specific resistance to the extremely low range of 1.1×10⁻⁴Ω·cm or more and 3.8×10⁻⁴ Ω·cm or less.

The surface roughness Ra of the transparent conductive layer influences the specific resistance of the transparent conductive layer as described above. The transparent conductive film includes the first undercoat layer formed by a wet coating method as an underlying layer of the transparent conductive layer. Since the thickness of the film substrate is generally more than that of other element, the influence of the film substrate on the surface roughness Ra of the upper layer is also increased. By forming the first undercoat layer by the wet coating method, the surface convexoconcave of the film substrate can be filled, and thereby the surface roughness Ra of the transparent conductive layer which will be formed on the upper layer can also be decreased.

Since the surface roughness Ra of the transparent conductive layer is the small value, a surface area brought into contact with water molecules in a high-temperature and high-humidity atmosphere can be decreased, which can eliminate an event which may cause deterioration in the transparent conductive layer as much as possible.

Furthermore, the deterioration in the transparent conductive layer is considered to be caused also by water and an organic gas ingredient or the like which are contained in the film substrate serving as the underlying layer of the transparent conductive layer and the undercoat layer containing an organic matter. However, since the transparent conductive film includes the third undercoat layer which is a metal oxide layer having a stoicheiometric composition as the underlying layer of the transparent conductive layer, this can serve as a barrier layer to also suppress the induction of deterioration from the underlying layer.

However, the third undercoat layer is a metal oxide layer having a stoicheiometric composition, and has a chemically stable lattice structure. Thereby, when the third undercoat layer is directly formed on the first undercoat layer, only a physical anchoring force acts between the third undercoat layer and the film substrate, which causes a decrease in adhesion. When the transparent conductive film is placed in a high-temperature and high-humidity environment in this state, peeling is caused between the first undercoat layer and the third undercoat layer, and moist-heat durability is not obtained.

Since the second undercoat layer which is a metal oxide layer having an oxygen deficient is formed between the first undercoat layer and the third undercoat layer in the transparent conductive film, the second undercoat layer acts as an adhesion layer. As a result, the peeling of the third undercoat layer can be prevented. Although the reason why the second undercoat layer exhibits an adhesive action is not sure, it is considered as follows. When the second undercoat layer has an oxygen deficient, a metal atom of which bond is not perfect exists in a metal oxide. This metal atom can form a covalent bond between the metal atom and an atom on the outermost surface of the first undercoat layer to improve the adhesion of the third undercoat layer to the underlying layer.

Thus, an adhesion improving action due to the second undercoat layer and a barrier action due to the third undercoat layer can suppress the accession of a deterioration factor such as water molecules from the back surface of the transparent conductive layer (the surface located on the side of the film substrate), and can prevent the peeling of the third undercoat layer in a severe environment. As a result, the resistance change of the transparent conductive layer can be decreased even after being subjected to a high-temperature and high-humidity environment for a prolonged time.

The second undercoat layer and the third undercoat layer are preferably formed by a sputtering method. This facilitates the formation of the target layer and allows the formation of a dense layer, which can efficiently suppress the accession of the deterioration factor to the back surface of the transparent conductive layer.

A laminated body of the film substrate and the at least three undercoat layers preferably has water vapor permeability of 0.01 g/m²·day or more and 3.0 g/m²·day or less. This can improve the blocking action of the water molecules due to the undercoat layer and can further improve the moist-heat resistance.

The second undercoat layer and the third undercoat layer preferably contain the same type of metal element. This can improve the affinity between the second undercoat layer and the third undercoat layer, and can further improve the adhesion.

The second undercoat layer is preferably an SiOₓ film (x is 1.0 or more and less than 2) from the viewpoint of transparency, durability, and adhesion.

The third undercoat layer is preferably an SiO₂ film from the viewpoint of transparency, compactness, and durability.

In one embodiment, the first undercoat layer may contain an organic resin. Thereby, a coating solution suitable for the wet coating method can be prepared, and the surface roughness can be stably decreased.

In one embodiment, the first undercoat layer may contain an organic resin, and may further contain an inorganic particle. The formulation of the inorganic particle can facilitate the adjustment of a refractive index and improve mechanical characteristics and durability.

The transparent conductive layer preferably has a refractive index of 1.89 or more and 2.20 or less. By adopting the refractive index of the range, the film density of the transparent conductive layer is increased, which provides a transparent conductive film having low specific resistance and moist-heat resistance.

The surface roughness Ra of the first undercoat layer located on a side of the second undercoat layer is preferably 0.1 nm or more and 1.5 nm or less. While the surface convexoconcave of the film substrate is filled by forming the first undercoat layer according to a wet coating method, the surface roughness Ra of the first undercoat layer is set to the above range, which sequentially provides the inheritance of the surface roughness Ra to the upper layer to easily set the surface roughness Ra of the transparent conductive layer to a predetermined range.

The thickness of the film substrate is preferably 20 μm or more and 200 μm or less. By setting the film substrate to the range, the transparent conductive film having an excellent appearance quality level can be produced. Since the transparent conductive film of the present invention has excellent moist-heat resistance, the deterioration in the transparent conductive layer can be preferably suppressed even when a thick film substrate is adopted. Furthermore, when the lower limit of the thickness of the film substrate is 40 μm or more, abrasion resistance and roll-to-roll transporting easiness can be improved.

The water content rate of the film substrate is preferably 0.001% to 3.0%. Thereby, the existing amount of the water molecules in the film substrate can be reduced, and the deterioration in the transparent conductive layer can be more efficiently suppressed.

The transparent conductive layer is preferably an indium-tin composite oxide layer. When the transparent conductive layer is the indium-tin composite oxide (hereinafter, referred to as “ITO”) layer, it is possible to form a transparent conductive layer that has lower resistance, high transparency, and good moist-heat resistance, and that can be easily crystallized.

The content of tin oxide in the indium-tin composite oxide layer is preferably 0.5% by weight to 15% by weight based on the total amount of tin oxide and indium oxide. This can increase a carrier density to advance lower specific resistance. The content of tin oxide can be appropriately selected in the range according to the specific resistance of the transparent conductive layer.

It is preferable that the transparent conductive layer has a structure where a plurality of indium-tin composite oxide layers are laminated; and at least two layers of the plurality of indium-tin composite oxide layers have existing amounts of tin different from each other. Not only the surface roughness Ra of the transparent conductive layer but also such a specific layer structure of the transparent conductive layer can advance the shortening of a crystal conversion time and the lower resistance of the transparent conductive layer.

In one embodiment of the present invention, it is preferable that the transparent conductive layer includes a first indium-tin composite oxide layer and a second indium-tin composite oxide layer in this order from the side of the film substrate; the content of tin oxide in the first indium-tin composite oxide layer is 6% by weight to 15% by weight based on the total amount of tin oxide and indium oxide; and the content of tin oxide in the second indium-tin composite oxide layer is 0.5% by weight to 5.5% by weight based on the total amount of tin oxide and indium oxide. The two-layered structure can achieve the shortening of the crystal conversion time of the transparent conductive layer, and suppress the low specific resistance value.

### BRIEF DESCRIPTION OF THE DRAWINGS

FIG. 1 is a schematic cross-sectional view showing a transparent conductive film according to one embodiment of the present invention.

### MODE FOR CARRYING OUT THE INVENTION

An embodiment of the present invention will be described below with reference to the drawings. However, parts which are unnecessary for the explanation are omitted, and there are parts which are enlarged or shrunk in the drawings to make the explanation easy. The terms each denoting a positional relationship such as the terms “upper” and “lower” are used merely for making the description easy unless the mentions are exceptional, and each never have an intention of limiting the constitution of the present invention.

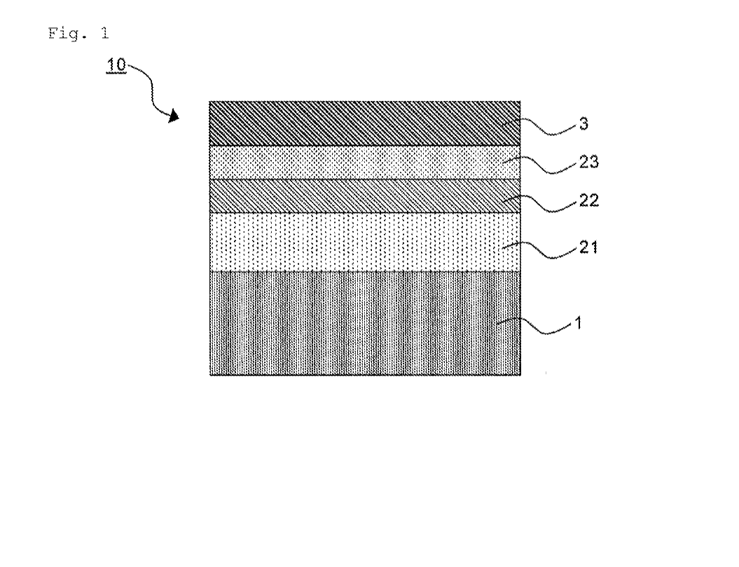

FIG. 1 is a schematic cross-sectional view showing a transparent conductive film according to one embodiment of the present invention. That is, a transparent conductive film 10 includes a transparent film substrate 1, at least three undercoat layers, and a crystalline transparent conductive layer 3 in this order. The at least three undercoat layers include a first undercoat layer 21 formed by a wet coating method, a second undercoat layer 22 that is a metal oxide layer having an oxygen deficient, and a third undercoat layer 23 that is a metal oxide layer having a stoicheiometric composition from the side of the film substrate 1.

### <Film Substrate>

The film substrate 1 has strength necessary for ease of handling, and has transparency in the visible light range. A film having excellent transparency, heat resistance, and surface smoothness is preferably used as the film substrate. Examples of the material for such a film include polyester such as polyethylene terephthalate or polyethylene naphthalate, polyolefin, poly(cycloolefin), polycarbonate, polyether sulfone, polyarylate, polyimide, polyamide, polystyrene, and homopolymers or copolymers of norbornene or the like. Among these, a polyester resin is appropriately used because the polyester resin has excellent transparency, heat resistance, and mechanical characteristics. Polyethylene terephthalate (PET) and polyethylene naphthalate (PEN) or the like are particularly suitable as the polyester resin. From the viewpoint of strength, it is preferable that a stretching treatment is performed on the film substrate, and it is more preferable that a biaxial stretching treatment is performed thereon. The stretching treatment is not particularly limited, and a known stretching treatment can be adopted.

A water content rate obtained according to the standard testing method JIS K 7251: 2002-B method of the film substrate 1 is preferably 0.001% to 3.0%, more preferably 0.001% to 2.0%, and still more preferably 0.001% to 1.0%. By setting the water content rate of the film substrate 1 to the above range, the amount of water molecules emitted from the film substrate 1 itself can be reduced. Therefore, the deterioration in the transparent conductive layer 3 can be prevented.

The thickness of the film substrate is not particularly limited, but the thickness is preferably 20 μm or more and 200 μm or less, and more preferably 40 μm or more and 150 μm or less.

When the thickness of the film is less than 20 μm, the appearance of the film may be deteriorated by the amount of heat during vacuum film formation. On the other hand, when the thickness of the film exceeds 200 μm, improvements in the abrasion resistance of a transparent conductive layer 2 and dotting characteristics when a touch panel or the like is formed may not be achieved. When the lower limit of the thickness of the film substrate is 40 μm or more, abrasion resistance and roll-to-roll transporting easiness can be improved.

The surface of the substrate may be previously subjected to sputtering, corona discharge treatment, bombard treatment, ultraviolet irradiation, electron beam irradiation, etching treatment, or undercoating treatment such that the adhesion of the substrate to the first undercoat layer 21 formed on the substrate can be improved. If necessary, the surface of the substrate may also be subjected to dust removing or cleaning by solvent cleaning and ultrasonic cleaning or the like, before the first undercoat layer 21 is formed.

The polymer film as the film substrate 1 is provided in a roll in which a long film is wound, and the transparent conductive layer 3 can be continuously formed thereon by a roll-to-roll method to give the long transparent conductive film.

### <First Undercoat Layer>

The first undercoat layer 21 is formed by a wet coating method. For example, in the wet coating method, an organic undercoat layer can be appropriately formed by diluting an organic resin or other additive with a solvent, applying the mixed material solution onto the film substrate, and subjecting the material solution to a curing treatment (for example, a heat curing treatment and a UV curing treatment).

The wet coating method can be appropriately selected according to the material solution and the desired characteristics of the undercoat layer. For example, a dip coating method, an air knife method, a curtain coating method, a roller coating method, a wire bar coating method, a gravure coating method, or an extrusion coating method or the like can be adopted.

In the undercoat layer formed by the wet coating method, a residual ingredient derived from a solvent or a resin or the like usually exists. For this reason, it is possible to analyze and detect the residual ingredient to specify whether the undercoat layer is a film formed by the wet coating method. The analysis method is not particularly limited. For example, the residual ingredient can be analyzed by electron spectrometry for chemical analysis (ESCA) and secondary ion mass spectrometry (SIMS) or the like. By analyzing an analysis sample while etching the analysis sample with predetermined element ions, the residual ingredient can be detected. Generally, carbon (C), hydrogen (H), and nitrogen (N) or the like can be adopted as the residual ingredient to be analyzed.

When an organic resin is used as a material for forming the undercoat layer, a dry type coating method cannot be usually adopted. Therefore, when the main ingredient of the undercoat layer is an organic resin, the undercoat layer can be regarded as a film produced by the wet coating method.

Conventionally, it was known that a certain level of moist-heat resistance of a transparent conductive layer can be secured by providing an undercoat layer according to a dry type coating method on the surface of a film substrate on which the transparent conductive layer is laminated (Patent Document 1). This is considered to be because the undercoat layer functions as a barrier layer for water vapor. However, as a result of the consideration of the present inventors, it became clear that the moist-heat resistance of the transparent conductive layer can be further improved by further providing a first undercoat layer by a wet coating method even when an undercoat layer having a multilayer structure is provided by such a dry type coating method on the surface of the substrate on which the transparent conductive layer is laminated.

Usually, it is not necessarily preferable that the transparent conductive film has the undercoat layer formed by the wet coating method from the viewpoint of moist-heat resistance. First, this reason is that a material suitable for the wet coating method tends to generally have high affinity with water, and is likely to keep water therein. Second, the reason is that the film density of the undercoat layer formed by the wet coating method tends to be lower than that formed by a dry type coating method such as a vacuum film formation method. Any fact shows that the undercoat layer formed by the wet coating method is likely to keep or transmit water derived from the surrounding environment. It is considered that the existence of such an undercoat layer does not advantageously act on moist-heat resistance.

Contrary to such a conventional technical common sense, the present inventors have combined the first undercoat layer formed by the wet coating method, and the second undercoat layer and third undercoat layer to be described later to provide an integral undercoat layer. This has surprisingly led to moist-heat resistance much higher than that of the conventional transparent conductive film having no wet coating film.

Generally, a long film substrate suitable for a roll-to-roll method has a constant surface roughness in order to secure good transporting property. In the transparent conductive film of the present embodiment, the transfer of the surface roughness of the film substrate to the transparent conductive layer can be suppressed by interposing the first undercoat layer. As a result, it is considered that the transparent conductive layer of the present embodiment has high smoothness, and a lower specific resistance value level can be achieved.

A material for forming the first undercoat layer 21 is preferably an organic resin having a refractive index of about 1.4 to 1.6 such as an acrylic resin, an urethane resin, a melamine resin, an alkyd resin, a siloxane-based polymer, and an organosilane condensate.

The first undercoat layer 21 preferably further contains an inorganic particle. This can provide easy adjustment of the refractive index and an improvement in mechanical strength. Examples of the inorganic particles include fine particles made of silicon oxide (silica), hollow nano-silica, titanium oxide, aluminum oxide, zinc oxide, tin oxide, and zirconium oxide or the like. Among these, fine particles made of silicon oxide (silica), titanium oxide, aluminum oxide, zinc oxide, tin oxide, and zirconium oxide are preferable. These may be used alone, or used in combination of two or more thereof. From the viewpoint of decreasing the surface roughness of the first undercoat layer, the average particle diameter of the particles is preferably 70 nm or less, and more preferably 30 nm or less.

By using a mixture of the organic resin and inorganic particle for the material for forming the first undercoat layer 21, the refractive index can be easily adjusted. The optical refractive index of the first undercoat layer 21 is preferably 1.55 to 1.75, more preferably 1.60 to 1.75, and still more preferably 1.63 to 1.70. The range can provide an improvement in transmissivity and a decrease in the reflectance difference between the surface of the undercoat layer and the surface of the transparent conductive layer when the transparent conductive layer is patterned.

The thickness of the first undercoat layer 21 may be appropriately set to such an extent that the effects of the present invention are not impaired. For example, when the first undercoat layer 21 does not contain the inorganic particle, the thickness of the first undercoat layer 21 is preferably 0.01 μm to 2.5 μm, more preferably 0.02 μm to 1.5 μm, and still more preferably 0.03 μm to 1.0 μm. On the other hand, when the first undercoat layer 21 contains the inorganic particle, the thickness is preferably 0.05 μm to 2.5 μm, more preferably 0.07 to 1.5 μm, and still more preferably 0.3 μm to 1.0 μm from the viewpoint of reducing the unevenness in the undercoat layer caused by the content particle. When the thickness of the first undercoat layer is too thin regardless of the existence or nonexistence of the inorganic particle, the surface convexoconcave of the film substrate may not be sufficiently filled, and the specific resistance of the transparent conductive layer cannot be stably reduced. When the thickness is too thick, the bending resistance of the first undercoat layer is deteriorated, which tends to be apt to cause cracks.

The surface roughness Ra of the first undercoat layer 21 is preferably 0.1 nm to 1.5 nm, more preferably 0.1 nm to 1.0 nm, still more preferably 0.1 nm to 0.8 nm, and particularly preferably 0.1 to 0.7 nm. When the surface roughness Ra of the first undercoat layer 21 is less than 0.1 nm, the adhesion between the first undercoat layer and the second undercoat layer is concernedly deteriorated. When the surface roughness Ra exceeds 1.5 nm, the specific resistance cannot be suppressed low. Herein, the surface roughness Ra means arithmetic average roughness Ra measured by AFM (Atomic Force Microscope).

### <Second Undercoat Layer>

The second undercoat layer 22 formed on the first undercoat layer 21 is a metal oxide layer having an oxygen deficient. Herein, “having an oxygen deficient” means a non-stoicheiometric composition. Examples of a metal oxide having an oxygen deficient include SiOₓ (x is 1.0 or more and less than 2), Al₂Oₓ (x is 1.5 or more and less than 3), TiOₓ (x is 1.0 or more and less than 2), Ta₂Oₓ (x is 2.5 or more and less than 5), ZrOₓ (x is 1.0 or more and less than 2), ZnOₓ (x is more than 0 and less than 1), and Nb₂Oₓ (x is 2.5 or more and less than 5.0). Among these, SiOₓ (x is 1.0 or more and less than 2) is preferable.

Herein, the metal oxide having an oxygen deficient, and furthermore the non-stoicheiometric composition can be confirmed by analyzing the oxidation state of the metal oxide by X-ray photoelectron spectroscopy.

When SiOₓ is taken for an example, the binding energy of a Si2p orbit may be calculated by X-ray photoelectron spectroscopy. When the calculated value is lower than the binding energy of SiO₂ having a stoicheiometric composition at this time, SiOₓ can be determined to have a non-stoicheiometric composition. Usually, if the calculated value is less than 104 eV, SiOₓ can be determined to have at least a non-stoicheiometric composition.

The second undercoat layer 22 is preferably formed by a dry process. An x value in the composition formula can be controlled by adjusting the introduction amount of oxygen into a chamber of a sputter device when a sputtering method is adopted, for example. When SiOₓ is taken for an example, and pure metal Si is used for a metal target, the introduction amount of oxygen may be adjusted within the range of 0% to 20% based on 100% of a sputtering gas. When suboxide (SiOₓ) is used for the metal target, the introduction amount of oxygen may be adjusted at a level lower than the range. The sputtered metal atom holds high kinetic energy, and collides with the surface of the first undercoat layer 21. This is continuously repeated to laminate the metal atoms, thereby forming the second undercoat layer. In that case, oxygen in the chamber is introduced into the film, and thereby the second undercoat layer having a constant amount of oxygen is formed.

Generally, the total amount of the contact surface between the layer having high smoothness such as the first undercoat layer and the upper layer is decreased, which does not sufficiently provide a physical anchoring force between the two layers to make it difficult to secure the adhesion. However, by providing the second undercoat layer as the upper layer of the first undercoat layer, a chemical bond can be formed between the metal atom of which the bond in the second undercoat layer is less than perfect and the atom existing on the outermost surface of the first undercoat layer 21, which is considered to provide firm adhesion due to the chemical bond even when the second undercoat layer 22 is formed on the first undercoat layer 21 having a small surface roughness.

When voids exist between the undercoat layers, water easily infiltrates and stagnates from the voids. The stagnating water becomes a factor for deteriorating the moist-heat resistance of the transparent conductive film. Since the transparent conductive film 10 has the second undercoat layer, the transparent conductive film 10 is less likely to cause voids between the second undercoat layer and the first undercoat layer, and has good moist-heat resistance.

The thickness of the second undercoat layer 22 is preferably 1 nm to 10 nm, and more preferably 1 nm to 8 nm. When the thickness is less than 1 nm, a continuous film cannot be formed, and the adhesion cannot be held. When the thickness is more than 10 nm, the absorption in the second undercoat layer 22 is expressed, which tends to cause a decrease in transmissivity.

The second undercoat layer 22 may not have a uniform composition in a thickness direction. For example, in only a neighborhood area including the interface between the second undercoat layer 22 and the first undercoat layer 21, an x value may be set to a low value. The x value may be set to a high value in the other area. When the x value in the neighborhood area is sufficiently low, high adhesion between the second undercoat layer 22 and the first undercoat layer can be secured. The range of the neighborhood area may be 10 to 30% of the thickness of the second undercoat layer.

Although the second undercoat layer 22 is preferably brought into contact with the first undercoat layer 21, a separate layer may be further interposed between the second undercoat layer 22 and the first undercoat layer 21 as long as the object of the present invention is not impaired.

Examples of the layer include a metal layer made of a metal which is not oxidized. The metal layer is interposed, and thereby the adhesion between the second undercoat layer 22 and the first undercoat layer 21 may be further improved.

### <Third Undercoat Layer>

The third undercoat layer 23 formed on the second undercoat layer 22 is substantially made of a metal oxide having a stoicheiometric composition. Examples of the formation material include SiO₂, Al₂O₃, TiO₂, Ta₂Os, ZrO₂, and ZnO. SiO₂ and Al₂O₃ are preferable, and SiO₂ is particularly preferable.

Herein, the stoicheiometric composition can be confirmed by analyzing the oxidation state of the metal oxide by X-ray photoelectron spectroscopy. However, in the X-ray photoelectron spectroscopy, even a layer obtained through a theoretical total oxidation state may not be determined to have a stoicheiometric composition depending on the conditions of measurement. In that case, it is determined whether the third undercoat layer has a stoicheiometric composition by measuring the refractive index of the metal oxide. When SiO₂ is taken for an example, and the refractive index is 1.43 or more and 1.49 or less, it is determined that SiO₂ has a stoicheiometric composition. When the refractive index is 1.50 or more and 1.90 or less, it is determined that SiO₂ has an oxygen deficient.

Herein, the refractive index can be obtained by measurement under conditions of a measurement wavelength: 195 nm to 1680 nm, and incidence angle: 65 degrees, 70 degrees, 75 degrees using a high-speed spectroscopic ellipsometer (M-2000DI manufactured by J. A. Woollam). The numerical value of the refractive index described herein is a refractive index of a wavelength of 550 nm.

The third undercoat layer 23 is preferably formed by a sputtering method. A particularly dense film can be stably formed by the sputtering method of the dry process techniques.

Since the density of the film formed by the sputtering method is higher than that formed by a vacuum deposition method, for example, the water vapor permeability is low, and the surface roughness is also suppressed, which can provide the transparent conductive film having excellent moist-heat resistance.

Since a reactant gas emitted from the film substrate 1 is suppressed by the second undercoat layer 22, the third undercoat layer 23 can be formed by carrying out reactive sputtering while introducing an oxygen gas in order that the third undercoat layer 23 stably has a stoicheiometric composition. When SiO₂ is taken for an example, and pure metal Si is used for the metal target, the introduction amount of oxygen may be 21% or more based on 100% of a sputtering gas, and preferably 21 to 60%. Suboxide (SiOₓ) used for the metal target may be adjusted at a level lower than the range. By forming a film while introducing a proper amount of oxygen gas, the third undercoat layer having a high film density and high transparency can be formed.

The atmosphere pressure when the third undercoat layer 23 is formed by sputtering is preferably 0.09 Pa to 0.5 Pa, and more preferably 0.09 Pa to 0.3 Pa. A higher-density metal oxide film can be formed by setting the atmosphere pressure to the above range.

In the present embodiment, the water vapor permeability of the laminated body (that is, the laminated structure excluding the transparent conductive layer from the transparent conductive film) of the film substrate 1 and three undercoat layers 21, 22, and 23 is preferably 0.01 g/m²·day or more and 3 g/m²·day or less, more preferably 0.01 g/m²·day or more and 1 g/m²·day or less, still more preferably 0.01 g/m²·day or more and 0.5 g/m²·day or less, and particularly preferably 0.01 g/m²·day or more and 0.3 g/m²·day or less. The water vapor permeability is obtained by measurement under conditions of 40° C./90% RH according to JIS K7129: 2008 attached document B. In order to obtain the laminated body, the transparent conductive layer may be removed from the transparent conductive film. The removing method is preferably wet etching according to a predetermined etchant and condition. When the transparent conductive layer is an ITO film, wet etching using hydrochloric acid is preferable. The condition of the wet etching may be appropriately set so that the ITO film is certainly removed. For example, the ITO film is usually immersed in hydrochloric acid (concentration: 10% by weight) at 50° C. for 2 minutes, and thereby the ITO film can be certainly removed even when the ITO film is amorphous or crystalline. When the ITO film is amorphous, the temperature condition may be room temperature (for example, 20° C.).

The second undercoat layer and the third undercoat layer preferably contain the same type of metal element. The constitution can provide an improvement in an adhesion force between the layers. Furthermore, the constitution is less likely to provide the formation of a clear layer boundary, which makes it possible to suppress the penetration of water between the second undercoat layer and the third undercoat layer.

The second undercoat layer and the third undercoat layer may be a continuous layer having no layer boundary. The constitution can eliminate the penetration of water between the second undercoat layer and the third undercoat layer. The continuous layer can be formed by forming the second undercoat layer, and then continuously forming the third undercoat layer without opening the surface of the second undercoat layer to the atmosphere when the sputtering method is adopted as the method for layer formation, for example.

Between the third undercoat layer and the transparent conductive layer, a metal oxide layer having an oxygen deficient may be further provided as a fourth undercoat layer. As the fourth undercoat layer, the same one as the second undercoat layer can be adopted. The constitution can improve the adhesion between the third undercoat layer and the transparent conductive layer, and further improve the moist-heat resistance.

### <Transparent Conductive Layer>

The constitutional material of the transparent conductive layer 3 is not particularly limited, and a metal oxide of at least one metal selected from the group consisting of In, Sn, Zn, Ga, Sb, Ti, Si, Zr, Mg, Al, Au, Ag, Cu, Pd and W is appropriately used. The metal oxide may further contain metal atoms indicated in the aforementioned group as needed. For example, it is preferable to use an indium-tin composite oxide (ITO) and an antimony-tin composite oxide (ATO) or the like, and it is particularly preferable to use ITO.

The surface roughness Ra of the transparent conductive layer 3 is 0.1 nm or more and 1.6 nm or less. The upper limit of the surface roughness Ra is preferably 1.5 nm or less, more preferably 1.3 nm or less, and still more preferably 1.2 nm or less. The lower limit of the surface roughness Ra is preferably 0.3 nm or more. When the surface roughness Ra is less than 0.1 nm, the blocking of the films is apt to occur, which may cause deterioration in appearance such as transparency, and poor processing. When the surface roughness Ra is more than 1.6 nm, the specific resistance and the moist-heat resistance tend to be deteriorated.

The transparent conductive layer 3 is preferably crystalline. The crystalline transparent conductive layer can have low specific resistance and moist-heat durability even if the transparent conductive layer 3 is a thin film. Although this reason is not limited by any theory, it is presumed as follows. It is considered that the crystalline transparent conductive layer has an energetically stabler structure than that of the amorphous transparent conductive layer, which can suppress the change in the specific resistance even when the crystalline transparent conductive layer is exposed in a moist-heat environment for a prolonged time.

Whether or not the transparent conductive layer 3 is crystalline can be determined by immersing the transparent conductive layer 3 in hydrochloric acid at 20° C. (concentration: 5% by weight) for 15 minutes when the transparent conductive layer 3 is the ITO film, thereafter washing with water and drying, and measuring the resistance between terminals at an interval of about 15 mm. Herein, it is determined that crystallization of the ITO layer into crystalline has been completed, when the resistance between the terminals at an interval of 15 mm is 10 kJ or less after immersing in hydrochloric acid (at 20° C., concentration: 5% by weight), washing with water and drying.

When the transparent conductive layer is amorphous, crystal conversion can be provided by a heat treatment. A heating temperature and heating time for the crystal conversion may be under a condition in which the transparent conductive layer can be certainly crystallized. From the viewpoint of productivity, the transparent conductive layer is heat-treated usually preferably at 150° C. for 45 minutes or less, and more preferably at 150° C. for 30 minutes or less.

A surface resistance value can be reduced by subjecting the transparent conductive layer to crystal conversion. The surface resistance value of the crystalline transparent conductive layer is preferably 40Ω/□ to 200Ω/□, more preferably 40Ω/□ to 150Ω/□, and still more preferably 40Ω/□ to 140Ω/□.

The crystalline transparent conductive layer 3 may have a low specific resistance value of 1.1×10⁻⁴ Ω·cm or more and 3.8×10⁻⁴ Ω·cm or less. The specific resistance value is preferably 1.1×10⁻⁴ Ω·cm or more and 3.5×10⁻⁴ Ω·cm or less, more preferably 1.1×10⁻⁴ Ω·cm or more and 3.4×10⁻⁴ Ω·cm or less, and still more preferably 1.1×10⁻⁴ Ω·cm or more and 3.2×10⁻⁴ Ω·cm or less.

When ITO (indium-tin composite oxide) is used as the materials which are used to form the transparent conductive layer 3, the content of tin oxide (SnO₂) in the metal oxide is preferably 0.5% by weight to 15% by weight, more preferably 3 to 15% by weight, still more preferably 5 to 12% by weight, and particularly preferably 6 to 12% by weight, based on the total amount of tin oxide and indium oxide (In₂O₃). When the amount of tin oxide is too small, the durability of the ITO film may be deteriorated. When the amount of tin oxide is too large, the crystallization of the ITO film becomes difficult, and the transparency and the stability of the resistance value may be insufficient.

The term “ITO” herein may be a composite oxide which contains at least indium (In) and tin (Sn), and may contain additional components other than indium and tin. Examples of the additional components include metal elements other than In and Sn. Specific examples thereof include Zn, Ga, Sb, Ti, Si, Zr, Mg, Al, Au, Ag, Cu, Pd, W, Fe, Pb, Ni, Nb, Cr, Ga, and a combination thereof. Although the content of the additional component is not particularly limited, the content may be 3% by weight or less.

The transparent conductive layer 3 may have a structure where a plurality of indium-tin composite oxide layers having existing amounts of tin different from each other are laminated. In this case, the number of the ITO films may be 2 or 3 or more.

When the transparent conductive layer 3 has a two-layered structure where a first indium-tin composite oxide layer and a second indium-tin composite oxide layer are laminated in this order from the side of the film substrate 1, the content of tin oxide in the first indium-tin composite oxide layer is preferably 6% by weight to 15% by weight, more preferably 6 to 12% by weight, and still more preferably 6.5 to 10.5% by weight, based on the total amount of tin oxide and indium oxide. The content of tin oxide in the second indium-tin composite oxide layer is preferably 0.5% by weight to 5.5% by weight, more preferably 1 to 5.5% by weight, and still more preferably 1 to 5% by weight, based on the total amount of tin oxide and indium oxide. By setting the amount of tin of each ITO layer to the above range, a transparent conductive film having small specific resistance and a short crystal conversion time due to heating can be formed.

When the transparent conductive layer 3 has a three-layered structure where a first indium-tin composite oxide layer, a second indium-tin composite oxide layer, and a third indium-tin composite oxide layer are laminated in this order from the side of the film substrate 1, the content of tin oxide in the first indium-tin composite oxide layer is preferably 0.5% by weight to 5.5% by weight, more preferably 1 to 4% by weight, and still more preferably 2 to 4% by weight, based on the total amount of tin oxide and indium oxide. The content of tin oxide in the second indium-tin composite oxide layer is preferably 6% by weight to 15% by weight, more preferably 7 to 12% by weight, and still more preferably 8 to 12% by weight, based on the total amount of tin oxide and indium oxide. The content of tin oxide in the third indium-tin composite oxide layer is preferably 0.5% by weight to 5.5% by weight, more preferably 1 to 4% by weight, and still more preferably 2 to 4% by weight, based on the total amount of tin oxide and indium oxide. By setting the amount of tin of each ITO layer to the above range, a transparent conductive film having small specific resistance and easily subjected to crystal conversion can be formed.

The thickness of the transparent conductive layer 3 (the total thickness in the case of the laminated structure) is preferably 15 nm or more and 40 nm or less, more preferably 15 nm or more and 35 nm or less, and still more preferably 15 nm or more and less than 30 nm. By setting the thickness to the above range, the transparent conductive layer 3 can be suitably applied for touch panels.

The method for forming the transparent conductive layer 3 is not particularly limited, and an appropriate method can be adopted according to materials used for forming the transparent conductive layer 3 and the required film thickness.

From the viewpoints of the uniformity of the film thickness and the film-forming efficiency, vacuum film-forming methods such as a chemical vapor deposition (CVD) method and a physical vapor deposition (PVD) method are suitably adopted. Among these, physical vapor deposition methods such as a vacuum vapor deposition method, a sputtering method, an ion plating method, and an electron beam evaporation method are preferable, and a sputtering method is particularly preferable.

From the viewpoint of obtaining a long laminated body, the transparent conductive layer 3 is preferably formed while transporting the film substrate by a roll-to-roll method or the like, for example.

As a sputtering target, the target having an ITO composition can be suitably used. In a sputtering film-forming process, first, a sputtering machine is preferably vented to a degree of vacuum (ultimate vacuum) of preferably 1×10⁻³ Pa or less, and more preferably 1×10⁻⁴ Pa or less to create an atmosphere in which water in the sputtering machine and impurities such as an organic gas generated from the substrate have been removed. This is because, when there are water and an organic gas in the machine, they terminate dangling bonds generated during a sputtering film-forming process and prevent the crystal growth of a conductive oxide such as ITO.

A sputtering film-formation process is performed under reduced pressure of 1 Pa or less while introducing a reactive gas such as an oxygen gas in the vented sputtering machine as necessary together with an inert gas such as Ar and transporting the substrate. The pressure upon forming a film is preferably 0.05 to 1 Pa, and more preferably 0.1 to 0.7 Pa. When the pressure for forming a film is too high, the film-forming speed tends to be decreased, and when the pressure is too low, discharge tends to become unstable.

The substrate temperature when ITO is formed into a film by sputtering is preferably −10 to 190° C., and more preferably −10 to 150° C.

A hard coat layer, an easy adhesion layer, and an anti-blocking layer or the like may be provided on the surface opposite to the surface of the film substrate 1 where the transparent conductive layer 3 is formed if necessary.

### EXAMPLES

The present invention will be described in detail with reference to Examples below. However, the present invention is not limited to the following Examples as long as the purport is not deviated. “Part(s)” in each Example is on a weight basis as long as there is no special notation.

### Example 1

### Formation of First Undercoat Layer

A UV curing type resin composition containing an acrylic resin and zirconium dioxide particles (average particle diameter: 20 nm) was diluted with methyl isobutyl ketone (MIBK) so that a solid content concentration was set to 5% by weight. The obtained diluted composition was applied onto one main surface of a polymer film substrate including a 50-μm-thick PET film (Diafoil (trade name) manufactured by Mitsubishi Plastics, Inc.), dried, and cured by UV irradiation, to form an organic undercoat layer having a film thickness of 0.5 μm (500 nm).

### (Formation of Second Undercoat Layer and Third Undercoat Layer)

On the organic undercoat layer, a second undercoat layer and a third undercoat layer were sequentially formed by a sputtering method using an AC/MF power source. The second undercoat layer was formed on the first undercoat layer by sputtering an Si target (manufactured by Mitsui Mining and Smelting Co., Ltd.) while Oz was introduced by impedance control into a vacuum atmosphere having atmosphere pressure of 0.3 Pa into which Ar was introduced (Ar:O₂=100:1). The obtained second undercoat layer was a 3-nm-thick SiOₓ (x=1.5) layer. The third undercoat layer was formed on the second undercoat layer by sputtering an Si target (manufactured by Mitsui Mining and Smelting Co., Ltd.) while O₂ was introduced by impedance control into a vacuum atmosphere having atmosphere pressure of 0.2 Pa into which Ar was introduced (Ar:O₂=100:40). The obtained third undercoat layer was a 20-nm-thick SiO₂ film.

### (Formation of Transparent Conductive Layer)

Furthermore, a transparent conductive layer including a 24-nm-thick indium-tin composite oxide layer was formed on the third undercoat layer by a DC magnetron sputtering method with a horizontal magnetic field of 30 mT in a vacuum atmosphere (0.3 Pa) into which Ar and O₂ (a flow ratio was Ar:O₂=99:1) were introduced, using a sintered object of 10% by weight tin oxide and 90% by weight indium oxide as a target. A transparent conductive film including the amorphous transparent conductive layer in the above procedures was produced. The produced transparent conductive film was heated with a 150° C. warm air oven for 45 minutes, to subject the transparent conductive layer to crystal conversion, thereby producing the transparent conductive film including a crystalline transparent conductive layer.

The obtained transparent conductive film was immersed in hydrochloric acid of concentration 5% by weight for 15 minutes, and thereafter rinsed with water and dried, and resistance between terminals with a 15 mm interval at optional three places on the surface of the transparent conductive layer was measured with a tester. At all the places, the measured value of surface resistance was 10 kΩ or less, and the crystal conversion of the transparent conductive layer was completed.

### Example 2

A transparent conductive film was produced in the same manner as in Example 1 except that the thickness of a first undercoat layer was set to 0.08 μm.

### Example 3

A transparent conductive film was produced in the same manner as in Example 1 except that the thickness of a first undercoat layer was set to 0.06 μm.

### Example 4

A transparent conductive film was produced in the same manner as in Example 1 except that a transparent conductive layer had a two-layered structure according to the following procedures.

Specifically, a first transparent conductive layer including a 22-nm-thick indium-tin composite oxide layer was formed by a DC magnetron sputtering method with a horizontal magnetic field of 30 mT in a vacuum atmosphere (0.3 Pa) into which Ar and Oz (a flow ratio was Ar:O₂=99:1) were introduced, using a sintered object of 10% by weight tin oxide and 90% by weight indium oxide as a target. On the first transparent conductive film, a second transparent conductive layer including a 2-nm-thick indium-tin composite oxide layer was formed by a DC magnetron sputtering method with a horizontal magnetic field of 30 mT in a vacuum atmosphere (0.3 Pa) into which Ar and O₂ (a flow ratio was Ar:O₂=99:1) were introduced, using a sintered object of 3% by weight tin oxide and 97% by weight indium oxide as a target.

### Example 5

A transparent conductive film was produced in the same manner as in Example 4 except that a horizontal magnetic field was set to 100 mT.

### Example 6

A transparent conductive film was produced in the same manner as in Example 4 except that a third undercoat layer was formed while O₂ was introduced by impedance control into a vacuum atmosphere having atmosphere pressure of 0.15 Pa into which Ar was introduced (Ar:O₂=100:40).

### Example 7

A transparent conductive film was produced in the same manner as in Example 4 except that a third undercoat layer was formed while O₂ was introduced by impedance control into a vacuum atmosphere having atmosphere pressure of 0.3 Pa into which Ar was introduced (Ar:O₂=100:40).

### Comparative Example 1

A transparent conductive film was produced in the same manner as in Example 1 except that a transparent conductive layer was not subjected to crystal conversion.

### Comparative Example 2

A transparent conductive film was produced in the same manner as in Example 2 except that the thickness of a first undercoat layer was set to 0.04 μm.

### Comparative Example 3

A transparent conductive film was produced in the same manner as in Example 1 except that a first undercoat layer was not formed.

### Comparative Example 4

A transparent conductive film was produced in the same manner as in Example 1 except that, as the third undercoat layer, silica sol (obtained by diluting COLCOAT P (manufactured by COLCOAT CO., LTD.) with ethanol in solid concentration of 2% by weight) was coated by a silica coating method, dried by heating at 150° C. for 2 minutes to be cured, thereby forming an SiO₂ layer having a thickness of 20 nm.

The obtained transparent conductive film was immersed in hydrochloric acid of concentration 5% by weight for 15 minutes, and thereafter rinsed with water and dried, and resistance between terminals with a 15 mm interval at optional three places on the surface of the transparent conductive layer was measured with a tester. At all the places, the measured value of the surface resistance was 10 kΩ or more, and the crystal conversion of the transparent conductive layer was not completed.

### Comparative Example 5

A transparent conductive film was produced in the same manner as in Example 1 except that a third undercoat layer was not formed.

The obtained transparent conductive film was immersed in hydrochloric acid of concentration 5% by weight for 15 minutes, and thereafter rinsed with water and dried, and resistance between terminals with a 15 mm interval at optional three places on the surface of the transparent conductive layer was measured with a tester. At all the places, the measured value of the surface resistance was 10 kΩ or more, and the crystal conversion of the transparent conductive layer was not completed.

### <Evaluation>

Measurements and valuation methods for the transparent conductive films produced in Examples and Comparative Examples are as follows. The evaluation results are shown in Table 1.

### (1) Measurement of Film Thickness

The thickness of each of the organic undercoat layer, SiOₓ film, SiO₂ film, and ITO film was measured by observing the cross section of the layer or film through a transmission electron microscope (“HF-2000” manufactured by Hitachi Ltd.).

(2) Surface Roughness Ra The surface roughness Ra was measured by AFM (Atomic Force

Microscope). Specifically, SPI3800 (manufactured by Seiko Instruments Inc.) was used as the AFM. The surface roughness Ra was confirmed by measurement under conditions of a contact mode, probe made of Si₃N₄ (spring constant: 0.09 N/m), and a scanning size of 1 μm □.

### (3) Water Vapor Permeability

An amorphous transparent conductive layer was immersed in hydrochloric acid (concentration: 10% by weight) at 20° C. for 2 minutes to remove the transparent conductive layer by etching, thereby forming a laminated film of a film substrate and undercoat layer. The laminated film was heated at 150° C. for 45 minutes. The water vapor permeability of the obtained laminated film was measured under the following test condition according to JIS K7129: 2008 attached document B using a test apparatus “PERMATRAN W3/33 (manufactured by MOCON)”.

Test temperature: 40° C.

Test humidity: 90% RH

Penetration direction: surface located on undercoat layer side is disposed on sensor side

### (4) Measurement of Specific Resistance of Crystalline ITO Film

The surface resistance (Q/O) of the obtained crystalline transparent conductive layer was measured by a four-point probe method in conformity with JIS K7194 (1994). Specific resistance was calculated from the thickness of the transparent conductive layer obtained by the above item (1) measurement of film thickness, and the surface resistance.

### (5) Moist-Heat Resistance

The surface resistance value of the obtained crystalline transparent conductive layer was measured in the procedures described in the above item (4). This was defined as the surface resistance value R0 at the initial stage. Next, the surface resistance value R500 after the crystalline transparent conductive layer was allowed to stand in a thermo-hygrostat (“LHL-113” manufactured by Espec Corporation) set to 85° C. 85% RH for 500 hours was measured. R500/R0 was obtained as the rate of change of the resistance from these values.

TABLE 1

| | | | | | | | Surface | | | |
|---|---|---|---|---|---|---|---|---|---|---|
| | Undercoat layer | | | ITO | | | roughness (Ra) | | | |
| | First | Second | Third | First | Second | Water vapor | First undercoat | | Specific | Moist-heat |
| | layer | layer | layer | layer | layer | permeability | layer | ITO | resistance × | test |
| | (μm) | (nm) | (nm) | (nm) | (nm) | g/m² · day | (nm) | (nm) | 10⁻⁴ (Ω · cm) | R500/RO |
| Example 1 | 0.5 | 3 | 20 | 24 | — | 0.2 | 0.6 | 1.0 | 3.4 | 1.2 |
| Example 2 | 0.08 | 3 | 20 | 24 | — | 0.2 | 0.7 | 1.1 | 3.4 | 1.3 |
| Example 3 | 0.06 | 3 | 20 | 24 | — | 0.2 | 0.9 | 1.3 | 3.6 | 1.4 |
| Example 4 | 0.5 | 3 | 20 | 22 | 2 | 0.2 | 0.6 | 1.0 | 3.2 | 1.2 |
| Example 5 | 0.5 | 3 | 20 | 22 | 2 | 0.2 | 0.6 | 1.0 | 2.1 | 1.2 |
| Example 6 | 0.5 | 3 | 20 | 22 | 2 | 0.1 | 0.6 | 1.0 | 3.2 | 1.1 |
| Example 7 | 0.5 | 3 | 20 | 22 | 2 | 0.6 | 0.6 | 1.0 | 3.2 | 1.2 |
| Comparative | 0.5 | 3 | 20 | 24 | — | 0.2 | 0.6 | 1.0 | 7.2 | 1.7 |
| Example 1 | | | | | | | | | | |
| Comparative | 0.04 | 3 | 20 | 24 | — | 0.2 | 1.4 | 1.8 | 4.0 | 1.6 |
| Example 2 | | | | | | | | | | |
| Comparative | — | 3 | 20 | 24 | — | 0.2 | — | 2.2 | 4.1 | 1.7 |
| Example 3 | | | | | | | | | | |
| Comparative | 0.5 | 3 | 20 (Wet | 24 | — | 10 | 0.5 | 0.8 | 4.7 | 1.6 |
| Example 4 | | | type) | | | | | | | |
| Comparative | 0.5 | 3 | — | 24 | — | 10 | 0.6 | 0.9 | 4.4 | 1.6 |
| Example 5 | | | | | | | | | | |

In the transparent conductive films of Examples, both the specific resistance and the moist-heat resistance were good. On the other hand, in Comparative Examples, both the specific resistance and the moist-heat resistance were poor.

### DESCRIPTION OF REFERENCE SIGNS

1: film substrate
21: first undercoat layer
22: second undercoat layer
23: third undercoat layer
3: transparent conductive layer
10: transparent conductive film

1. A transparent conductive film comprising:
a transparent film substrate;
at least three undercoat layers; and
a crystalline transparent conductive layer in this order,
wherein:
the at least three undercoat layers comprise:
a first undercoat layer formed by a wet coating method;
a second undercoat layer that is a metal oxide layer having an oxygen deficient; and
a third undercoat layer that is a metal oxide layer having a stoichiometric composition from a side of the film substrate;
the transparent conductive layer has a surface roughness Ra of 0.1 nm or more and 1.6 nm or less; and
the transparent conductive film has specific resistance of 1.1×10⁻⁴ Ω·cm or more and 3.8×10⁻⁴ Ω·cm or less.

2. The transparent conductive film according to claim 1, wherein the second undercoat layer and the third undercoat layer are formed by a sputtering method.

3. The transparent conductive film according to claim 1, wherein a laminated body of the film substrate and the at least three undercoat layers has water vapor permeability of 0.01 g/m²·day or more and 3.0 g/m²·day or less.

4. The transparent conductive film according to claim 1, wherein the second undercoat layer and the third undercoat layer contain the same type of metal element.

5. The transparent conductive film according to claim 1, wherein the second undercoat layer is an SiOₓ film (x is 1.0 or more and less than 2).

6. The transparent conductive film according to claim 1, wherein the third undercoat layer is an SiO₂ film.

7. The transparent conductive film according to claim 1, wherein the first undercoat layer contains an organic resin.

8. The transparent conductive film according to claim 7, wherein the first undercoat layer further contains an inorganic particle.

9. The transparent conductive film according to claim 1, wherein the transparent conductive layer has a refractive index of 1.89 or more and 2.20 or less.

10. The transparent conductive film according to claim 1, wherein a surface roughness Ra of the first undercoat layer located on a side of the second undercoat layer is 0.1 nm or more and 1.5 nm or less.

11. The transparent conductive film according to claim 1, wherein the film substrate has a water content rate of 0.001% to 3.0%.

12. The transparent conductive film according to claim 1, wherein the film substrate has a thickness of 20 μm or more and 200 μm or less.

13. The transparent conductive film according to claim 1, wherein the film substrate has a thickness of is 40 μm or more and 200 μm or less.

14. The transparent conductive film according to claim 1, wherein the transparent conductive layer is an indium-tin composite oxide layer.

15. The transparent conductive film according to claim 14, wherein a content of tin oxide in the indium-tin composite oxide layer is 0.5% by weight to 15% by weight based on the total amount of tin oxide and indium oxide.

16. The transparent conductive film according to claim 1,
wherein:
the transparent conductive layer has a structure where a plurality of indium-tin composite oxide layers are laminated; and
at least two layers of the plurality of indium-tin composite oxide layers have existing amounts of tin different from each other.

17. The transparent conductive film according to claim 16,
wherein:
the transparent conductive layer has a first indium-tin composite oxide layer and a second indium-tin composite oxide layer in this order from the side of the film substrate;
a content of tin oxide in the first indium-tin composite oxide layer is 6% by weight to 15% by weight based on the total amount of tin oxide and indium oxide; and
a content of tin oxide in the second indium-tin composite oxide layer is 0.5% by weight to 5.5% by weight based on the total amount of tin oxide and indium oxide.
